(19) United States
(12) Patent Application Publication
(10) Pub. No.: US 2024/0294771 A1
(43) Pub. Date: Sep. 5, 2024

(54) ANTI-REFLECTIVE COATING COMPOSITION AND CROSSLINKABLE POLYMER

(71) Applicant: TAN KAH KEE INNOVATION LABORATORY, Xiamen (CN)

(72) Inventors: Aiqiang Zhang, Xiamen (CN); Renzhi Chen, Xiamen (CN); Mark Neisser, Xiamen (CN); Yimin Jiang, Xiamen (CN); Yuan Chen, Xiamen (CN)

(21) Appl. No.: 18/644,623

(22) Filed: Apr. 24, 2024

Related U.S. Application Data
(63) Continuation of application No. PCT/CN2022/072277, filed on Jan. 17, 2022.

(30) Foreign Application Priority Data
Oct. 25, 2021 (CN) 202111241133.4

(51) Int. Cl. C09D 5/00; C09D 7/20; C09D 7/45; C09D 7/63; C09D 133/26; G03F 7/09

(52) U.S. Cl. CPC C09D 5/006; C09D 7/20; C09D 7/45; C09D 7/63; C09D 133/26; G03F 7/091

(57) ABSTRACT

An anti-reflective coating composition comprises an organic polymer. The organic polymer comprises a crosslinkable polymer. The crosslinkable polymer comprises a monomer unit formed by a monomer represented by formula (I):

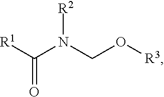

wherein R¹ is selected from substituted or unsubstituted C2-C10 alkenyl, and R² and R³ are each independently selected from H, substituted or unsubstituted C1-C6 alkyl, and substituted or unsubstituted C6-C20 aryl. Compared with the prior art, the subject crosslinkable polymer comprises the monomer unit that can be self-crosslinked with functional groups such as hydroxyl, amino, and sulfhydryl, such that a crosslinking agent does not need to be added to a coating. The generation of gas during baking process of the composition can be effectively reduced or eliminated, and some unnecessary cleaning process is avoided by doing so. The pattern damage due to solid particle caused by gas condensation can also be avoided. The overall process flow can be simplified and the relevant cost can be reduced.

### CROSS-REFERENCE TO RELATED APPLICATION

The present application is a continuation of International Application No. PCT/CN2022/072277, filed Jan. 17, 2022, which claims priority to Chinese patent application No. 202111241133.4, filed Oct. 25, 2022, which are both hereby incorporated by reference in their entirety.

### TECHNICAL FIELD

The present disclosure belongs to the technical field of semiconductors, and especially, it relates to an anti-reflective coating composition and a crosslinkable polymer.

### BACKGROUND

The photolithographic process is one of the most important processes during manufacturing semiconductor devices. In particular, the photolithographic process, by utilizing the photosensitive function of a photoresist, transfers a fine circuit pattern from mask to photoresist and then to silicon wafer substrate eventually, to make preparations for subsequent etching and ion implantation.

However, as the more and more highly integrated semiconductor devices is developed, a shorter incident light wavelength from i-line (365 nm) to deep ultraviolet-line (248 nm and 193 nm) is required to meet higher and higher resolution requirement of IC chip during exposure process. The shorter and shorter wavelength tendency of incident light induces the more and more severe light diffusion reflection from substrates and standing waves, etc., which will seriously cause image distortion and poor resolution etc. issues.

To overcome the above problems, an effective solution is to introduce an anti-reflective coating layer between the photoresist and the substrate to reduce or eliminate reflections from the substrate. The anti-reflective coating layer mainly includes the following two types: an inorganic coating layer and an organic coating layer comprising a light-absorbing component and a polymer. Among them, the inorganic anti-reflective coating layer has the following drawbacks: required special equipment, additional process steps, subsequent difficulties to rework. While as organic anti-reflective coating layer, similar to photoresist, can be coated by spin-on process, which will effectively simplify overall process flow and reduce costs. Therefore, it is widely applied and studied.

After the organic anti-reflective coating process, a high-temperature baking is applied to further crosslink and cure it. During the baking process, “outgassing” from some of its chemical components occurs, which causes great problem. Typically, the “outgassing” mainly comes from small molecular compounds such as crosslinking agent etc., and the equipment exhaust system cannot effectively remove them. The outgassing species condense on the inner chamber wall of baking equipment. Such condensates could fall off onto subsequent wafers, leading to cross contamination.

### SUMMARY

The present disclosure is to provide an anti-reflective coating composition and crosslinkable polymer, which can effectively reduce or eliminate the “outgassing” during baking process.

The present disclosure provides an anti-reflective coating composition, comprising an organic polymer;
the organic polymer comprises a crosslinkable polymer;
the crosslinkable polymer comprises a monomer unit formed by a monomer represented by formula (I):

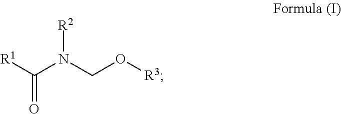

wherein R¹ is selected from substituted or unsubstituted C₂-C₁₀ alkenyl;
R² and R³ each are independently selected from a group consisting of H, substituted or unsubstituted C₁-C₆ alkyl, and substituted or unsubstituted C₆-C₂₀ aryl;
substituents in the substituted C₂-C₁₀ alkenyl, substituted C₁-C₆ alkyl, and substituted C₆-C₂₀ aryl each are independently one or more selected from a group consisting of C₁-C₈ alkyl, C₁-C₆ alkoxy and phenyl.

Preferably, R¹ is selected from substituted or unsubstituted C₂-C₄ alkenyl;
R² and R³ each are independently selected from a group consisting of H, substituted or unsubstituted C₁-C₃ alkyl, and substituted or unsubstituted C₆-C₁₀ aryl.

Preferably, the mass of the organic polymer is 2%-10% of the mass of the anti-reflective coating composition; the mass of the crosslinkable polymer is 10%-100% of the mass of the organic polymer; the amount of the monomer unit formed by the monomer represented by formula (I) in the crosslinkable polymer is 5 wt %-80 wt %.

Preferably, the crosslinkable polymer comprises a functional group and/or the organic polymer further comprises a first polymer; the first polymer comprises a functional group; the functional group is one or more selected from a group consisting of hydroxyl, amino and sulfhydryl.

Preferably, the mass of the monomer unit comprising the functional group is 20%-300% of the mass of the monomer unit formed by the monomer represented by formula (I).

Preferably, the crosslinkable polymer further comprises a light-absorbing organic chromophore and/or the first polymer further comprises a light-absorbing organic chromophore and/or the organic polymer further comprises a second polymer; the second polymer comprises a light-absorbing organic chromophore; the light-absorbing organic chromophore is one or more selected from a group consisting of substituted or unsubstituted aryl, polyhaloalkyl, and a substituted or unsubstituted isocyanatourea group.

Preferably, the mass of the monomer unit comprising the light-absorbing organic chromophore is 10%-85% of the mass of the organic polymer.

Preferably, the anti-reflective coating composition further comprises a thermal acid generator, a photoacid generator, a surfactant and a solvent; the mass of the thermal acid generator is 0.1%-15% of the mass of the anti-reflective coating composition; the mass of the photoacid generator is 0%-15% of the mass of the anti-reflective coating composition; the mass of the surfactant is 0%-20% of the mass of the anti-reflective coating composition; the mass of the solvent is 90%-99% of the mass of the anti-reflective coating composition.

Preferably, the thermal acid generator is selected from a group consisting of ionic thermal acid generators and/or non-ionic thermal acid generators; the ionic thermal acid generators are one or more selected from a group consisting of dodecylsulfonic acid triethylamine salt, p-toluenesulfonic acid amine salt and a p-toluenesulfonate; the non-ionic thermal acid generators are one or more selected from a group consisting of a trifluoro-methanesulfonic acid cyclohexyl ester, methyl trifluoromethanesulfonate, 2,4,6-triisopropylbenzenesulfonic acid cyclohexyl ester, 2-nitrobenzyl p-toluenesulfonate, benzoin tosylate, 2-nitrobenzyl tosylate, hexahydro-1,3,5-tris(2,3-dibromopropyl)-1,3,5-triazine-2,4,6-trione, organic sulfonic acid alkyl ester, p-toluenesulfonic acid, dodecylbenzenesulfonic acid, oxalic acid, phthalic acid, phosphoric acid, camphorsulfonic acid and salts of the above materials;
the photoacid generator is one or more selected from a group consisting of iodonium (tetra-t-butylphenyl)-triflate, sulfonium triphenytriflate, triphenylsulfonium trifluoromethanesulfonate, (p-t-butoxyphenyl)diphenylsulfonium triflate, tris(p-t-butoxyphenyl)sulfonium triflate, triphenylsulfonium p-toluenesulfonate, 2-nitrobenzyl-p-toluenesulfonate, 2,6-dinitrobenzyl-p-toluenesulfonate, 2,4-dinitrobenzyl-p-toluenesulfonate, benzoin tosylate, N-hydroxysuccinimide trifluoromethanesulfonic acid ester, 1,2,3-tris(methanesulfonyloxy)benzene, 1,2,3-tris(trifluoromethanesulfonyloxy)benzene, 1,2,3-tris(p-toluenesulfonyloxy)benzene, bis(benzenesulfonyl)azimethane, bis(p-toluenesulfonyl)azimethane, bis-O-(p-toluenesulfonyl)-a-dimethylglyoxime, bis-O-(n-butanesulfonyl)-a-dimethylglyoxime, N-hydroxysuccinimide methanesulfonate, N-hydroxysuccinimide triflate, phenylbis(trichloromethyl)-s-triazine, 2-(4-methoxyphenyl)-4,6-bis(trichloromethyl)-1,3,5-triazine and 2-(4-methoxynaphthyl)-4,6-bis(trichloromethyl)-1,3,5-triazine;
the surfactant is one or more selected from a group consisting of polyoxyethylene lauryl (dodecyl) ether, polyoxyethylene stearyl ether, polyoxyethylene hexadecyl ether, polyoxyethylene oleyl ether, polyoxyethylene octylphenol ether, polyoxyethylene nonylphenol ether, polyoxyethylene-polyoxypropylene block copolymer, sorbitan monolaurate, sorbitan monopalmitate (hexadecanoate), sorbitan monostearate, sorbitan monooleate (9-octadecenate), sorbitan trioleate, sorbitan tristearate, polyoxyethylene sorbitan monolaurate, polyoxyethylene sorbitan monopalmitate (hexadecanoate), polyoxyethylene sorbitan monostearate, polyoxyethylene sorbitan monooleate (9-octadecenate), polyoxyethylene sorbitan trioleate, and polyoxyethylene sorbitan tristearate;
the solvent is one or more selected from a group consisting of ethylene glycol monomethyl ether, ethylene glycol monoethyl ether, methylcellosolve acetate, ethylcellosolve acetate, diethylene glycol monomethyl ether, diethylene glycol monoethyl ether, propylene glycol, propylene glycol monomethyl ether, propylene glycol monomethyl ether acetate, propylene glycol propyl ether acetate, toluene, xylene, methyl ethyl ketone, cyclopentanone, cyclohexanone, ethyl 2-hydroxypropionate, methyl 2-hydroxy-3-methylbutyrate, methyl 3-methoxypropionate, ethyl 3-methoxypropionate, ethyl 3-ethoxypropionate, methyl 3-ethoxypropionate, methyl pyruvate, ethyl pyruvate, ethyl acetate, butyl acetate, ethyl lactate, butyl lactate, N,N-dimethylformamide, and N-methylpyrrolidone.

The present disclosure further provides a crosslinkable polymer, comprising a monomer unit formed by a monomer represented by formula (I);

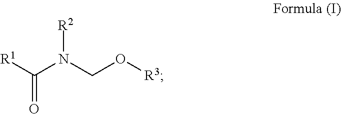

wherein R¹ is selected from substituted or unsubstituted C₂-C₁₀ alkenyl;
R² and R³ each are independently selected from a group consisting of H, substituted or unsubstituted C₁-C₆ alkyl, and substituted or unsubstituted C₆-C₂₀ aryl;
substituents in the substituted C₂-C₁₀ alkenyl, substituted C₁-C₆ alkyl, and substituted C₆-C₂₀ aryl each are independently one or more selected from a group consisting of C₁-C₈ alkyl, C₁-C₆ alkoxy and phenyl.

The present disclosure provides a method to make the above crosslinkable polymer including by mixing monomers, represented by formula (I), with an initiator in a solvent and heating them to conduct a polymerization reaction.

The present application also provides a method for forming a pattern image with photoresist during manufacturing semiconductor device, comprising a film-forming step of the above anti-reflective coating composition, a film-forming step of photoresist, and subsequent irradiation-exposing step followed by the developing step of photoresist.

The present disclosure provides an anti-reflective coating composition, comprising an organic polymer; the organic polymer comprises a crosslinkable polymer; the crosslinkable polymer comprises a monomer unit formed by a monomer represented by formula (I), wherein R¹ is selected from substituted or unsubstituted C₂-C₁₀ alkenyl; R² and R³ each are independently selected from a group consisting of H, substituted or unsubstituted C₁-C₆ alkyl, and substituted or unsubstituted C₆-C₂₀ aryl; substituents in the substituted C₂-C₁₀ alkenyl, substituted C₁-C₆ alkyl, and substituted C₆-C₂₀ aryl each are independently selected from a group consisting of C₁-C₈ alkyl or phenyl. As compared with the prior art, the crosslinkable polymer provided by the present disclosure comprises a monomer unit that can be self-crosslinked with functional groups such as hydroxyl, amino, and the like, such that it does not need to add a crosslinking agent to the coating layer. Gas generation of a composition during its baking process can be effectively reduced or eliminated. By doing so, unnecessary cleaning processes are avoided while the patterns damage due to falling of solid particles formed by gas condensation is significantly reduced or eliminated. Therefore, the overall process flow can be simplified and the relevant cost could be reduced effectively.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

FIG. 1 is a Hydrogen Nuclear Magnetic Resonance (1H-NMR) spectrogram of the polymer obtained in Example 1 of the present disclosure;

FIG. 2 is a 1H-NMR spectrogram of the polymer obtained in Example 2 of the present disclosure;

FIG. 3 is a 1H-NMR spectrogram of the polymer obtained in Example 3 of the present disclosure;

FIG. 4 is a 1H-NMR spectrogram of the polymer obtained in Example 4 of the present disclosure;

FIG. 5 is a 1H-NMR spectrogram of the polymer obtained in Example 5 of the present disclosure;

FIG. 6 is a 1H-NMR spectrogram of the polymer obtained in Example 6 of the present disclosure;

FIG. 7 is a 1H-NMR spectrogram of the polymer obtained in Example 7 of the present disclosure;

FIG. 8 is a structural diagram of the apparatus used in the examples of the present disclosure for evaluating the outgassing effect;

FIG. 9 is a chart showing the results of outgassing evaluations for the anti-reflective coating compositions obtained in Examples 8 to 12 and Comparative Example 1 of the present disclosure;

FIG. 10 is a Scanning Electron Microscopy (SEM) image showing the pattern obtained after applying the anti-reflective coating composition obtained in Example 8 of the present disclosure in photolithography; and

FIG. 11 is an SEM image showing the pattern obtained by applying the anti-reflective coating composition obtained in Example 8 of the present disclosure in photolithographic slicing.

### DETAILED DESCRIPTION

The following contents, with reference to the examples of the present disclosure, clearly and completely describe the technical solutions in the examples of the present disclosure, and obviously, the described examples are only a part of the examples of the present disclosure, but not all the examples. Based on the examples in the present disclosure, all other examples acquired by those skilled in the art, under the premise of not making any creative efforts, belong to the protection scope of the present disclosure.

The present disclosure provides a crosslinkable polymer, comprising a monomer unit formed by a monomer represented by formula (I);

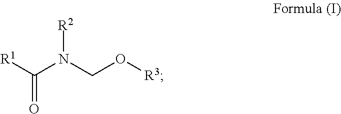

wherein R¹ is substituted or unsubstituted C₂-C₁₀ alkenyl, preferably substituted or unsubstituted C₂-C₈ alkenyl, more preferably substituted or unsubstituted C₂-C₆ alkenyl, further preferably substituted or unsubstituted C₂-C₄ alkenyl, and most preferably C₂-C₃ alkenyl; the number of the double bonds in the alkenyl may be one or more; in the present disclosure, the number of the double bonds in the alkenyl is preferably 1 to 2, and more preferably 1;
R² and R³ each are independently selected from a group consisting of H, substituted or unsubstituted C₁-C₆ alkyl, and substituted or unsubstituted C₆-C₂₀ aryl, preferably selected from a group consisting of H, substituted or unsubstituted C₁-C₆ alkyl, and substituted or unsubstituted C₆-C₁₅ aryl, more preferably selected from a group consisting of H, substituted or unsubstituted C₁-C₄ alkyl, and substituted or unsubstituted C₆-C₁₀ aryl, and further preferably selected from a group consisting of H, substituted or unsubstituted C₁-C₂ alkyl, and substituted or unsubstituted phenyl;
substituents in the substituted C₂-C₁₀ alkenyl, substituted C₁-C₆ alkyl, and substituted C₆-C₂₀ aryl each are independently selected from a group consisting of C₁-C₈ alkyl or phenyl, preferably selected from a group consisting of C₁-C₃ alkyl or phenyl, and more preferably selected from a group consisting of methyl, ethyl, C₁-C₆ alkoxy or phenyl.

An amount of the monomer unit formed by the monomer represented by formula (I) in the crosslinkable polymer is preferably 5 wt %-80 wt %, more preferably 10 wt %-76 wt %, further preferably 15 wt %-55 wt %, and most preferably 15 wt %-53 wt %; in the examples provided by the present disclosure, the amount of the monomer unit formed by the monomer represented by formula (I) in the crosslinkable polymer is specifically 15 wt %, 18 wt %, 53 wt %, 76 wt %, or 28.8 wt %.

The crosslinkable polymer, in addition to the monomer unit formed by the monomer represented by formula (I), preferably comprises an acrylates monomer unit; the acrylates monomer for forming the acrylates monomer unit are not particularly limited as long as they are acrylic monomers well known to those skilled in the art, and in the present disclosure, they are preferably substituted or unsubstituted alkyl acrylate and substituted or unsubstituted alkyl methacrylate; the number of carbon atoms in the alkyl groups of the substituted or unsubstituted alkyl acrylate and substituted or unsubstituted alkyl methacrylate is preferably 1-8, more preferably 1-6, and further preferably 1-4; the substituents in the substituted or unsubstituted alkyl acrylate and substituted or unsubstituted alkyl methacrylate each, independently, are preferably one or more selected from a group consisting of hydroxyl, amino, sulfhydryl, halogen and light-absorbing chromophore; the light-absorbing organic chromophore is preferably one or more selected from a group consisting of substituted or unsubstituted aryl, polyhaloalkyl, and a substituted or unsubstituted isocyanatourea ester group; among them, the substituted or unsubstituted aryl, not being particularly limited, may be substituted or unsubstituted monocyclic aryl or substituted or unsubstituted polycyclic aryl, and in the present disclosure, it is preferably substituted or unsubstituted phenyl, substituted or unsubstituted naphthyl, substituted or unsubstituted anthryl, or substituted or unsubstituted quinolyl; the number of carbon atoms of the alkyl in the polyhaloalky is preferably 1-10, more preferably 1-8, further preferably 1-6, still preferably 1-4, and most preferably 1-2; the halogens in the polyhaloalkyl are preferably one or more of bromine and iodine; the number of the halogens in the polyhaloalkyl is preferably 2-4, and more preferably 3-4; the substituents in the substituted aryl and substituted isocyanatourea ester group each are independently one or more selected from a group consisting of C₁-C₈ alkyl, C₆-C₁₀ aryl, hydroxyl, carbonyl and ether group.

According to the present disclosure, the acrylates monomer unit in the crosslinkable polymer preferably comprises a substituted acrylates monomer unit containing at least one of halogen and light-absorbing chromophore, and an acrylates monomer unit containing a functional group; the functional group is preferably one or more selected from a group consisting of hydroxyl, amino and sulfhydryl; the mass of the acrylates monomer unit containing the functional group is preferably 5%-50%, more preferably 5%-30%, further preferably 10%-30%, still preferably 15%-25%, and most preferably 15%-20%, of the mass of the acrylate monomer unit in the crosslinkable polymer; the mass of the substituted acrylates monomer unit containing at least one of the halogen and the light-absorbing chromophore is preferably 10%-50%, more preferably 20%-50%, further preferably 30%-50%, still preferably 30%-40%, and most preferably 34%-40%, of the mass of the acrylate monomer unit in the crosslinkable polymer.

The present disclosure provides a method to make the above crosslinkable polymer including by mixing monomers, represented by formula (I), with an initiator in a solvent and heating them to conduct a polymerization reaction.

The monomer in the system of the present disclosure, in addition to the monomer represented by formula (I), include other monomer that, particularly, may be selected according to the kinds of the monomer units contained in the crosslinkable polymer, and in the present disclosure, preferably, they further include an acrylates monomer unit; the kinds of the acrylates monomer unit are as described above, and no detail is further provided here; the mass of the monomer represented by formula (I) is preferably 5%-80%, more preferably 10%-76%, further preferably 15%-55%, and most preferably 15%-53%, of the mass of the total monomers; in the examples provided by the present disclosure, the mass of the monomer represented by formula (I) is particularly 15%, 18%, 53%, 76% or 28.8% of the mass of the total monomers; the initiator is not particularly limited as long as it is an initiator well known to those skilled in the art, and in the present disclosure, it is preferably an azo initiator; in the examples provided by the present disclosure, the initiator is particularly azobisisobutyronitrile; the solvent is not particularly limited as long as it is an organic solvent well known to those skilled in the art, and in the examples provided by the present disclosure, it is particularly tetrahydrofuran; the concentration of the monomers in the reaction system is preferably 0.1 g/mL-0.5 g/mL; the heating is preferably conducted to flux for performing a polymerization reaction; the time of the polymerization reaction is preferably 15 h-30 h, more preferably 20 h-26 h, and further preferably 24 h.

After the polymerization reaction is finished, n-hexane is preferably used for precipitation, and after drying, a crosslinkable polymer is obtained.

The present disclosure also provides an anti-reflective coating composition, comprising an organic polymer;
the organic polymer comprises a crosslinkable polymer;
the crosslinkable polymer comprises a monomer unit formed by a monomer represented by formula (I):

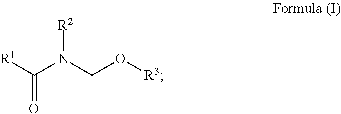

wherein R¹ is substituted or unsubstituted C₂-C₁₀ alkenyl;
R² and R³ each are independently selected from a group consisting of H, substituted or unsubstituted C₁-C₆ alkyl, and substituted or unsubstituted C₆-C₂₀ aryl;
substituents in the substituted C₂-C₁₀ alkenyl, substituted C₁-C₆ alkyl, and substituted C₆-C₂₀ aryl each are independently selected from a group consisting of C₁-C₅ alkyl or phenyl.

Among them, the crosslinkable polymer is described above, and no detail is further provided here.

In the present disclosure, the mass of the organic polymer is preferably 2%-10%, more preferably 2%-8%, further preferably 3%-7%, still preferably 3%-5%, and most preferably 3%-4%, of the mass of the anti-reflective coating composition.

The mass of the crosslinkable polymer is preferably 10%-100%, and more preferably 15%-100%, of the mass of the organic polymer.

According to the present disclosure, the crosslinkable polymer comprises functional groups and/or the organic polymer further comprises a first polymer; the first polymer comprises a functional group; that is, the organic polymer comprises the functional group, and among them, either the crosslinkable polymer comprises the functional group or the other polymers comprised in the organic polymer comprise the functional group, or both of them comprise the functional group simultaneously; the functional group is preferably hydroxyl and/or amino. In the present disclosure, the mass of the monomer unit containing the functional group is preferably 20%-300%, more preferably 30%-200%, and still more preferably 35%-200%, of the mass of the monomer unit formed by the monomer represented by formula (I).

To enable the anti-reflective coating composition to absorb optional active light back to the photoresist, the crosslinkable polymer further comprises an light-absorbing organic chromophore and/or the first polymer further comprises a light-absorbing organic chromophore and/or the organic polymer further comprises a second polymer; the second polymer comprises a light-absorbing organic chromophore; that is, the organic polymer comprises a light-absorbing organic chromophore that may be grafted either to the crosslinkable polymer or to the first polymer and that is also positioned on the second polymer rather than the above two polymers, and alternatively, two of them or three of them comprise a light-absorbing organic chromophore, which are not particularly limited; the light-absorbing organic chromophore is not particularly limited as long as it is a light-absorbing organic chromophore well known to those skilled in the art, and the light-absorbing organic chromophore in the present disclosure is one or more selected from a group consisting of a substituted or unsubstituted aryl, polyhaloalkyl, and a substituted or unsubstituted isocyanatourea group; among them, the substituted or unsubstituted aryl, not being particularly limited, may be substituted or unsubstituted monocyclic aryl or substituted or unsubstituted polycyclic aryl, and in the present disclosure, it is preferably substituted or unsubstituted phenyl, substituted or unsubstituted naphthyl, substituted or unsubstituted anthryl, or substituted or unsubstituted quinolyl; the number of carbon atoms of the alkyl in the polyhaloalky is preferably 1-10, more preferably 1-8, further preferably 1-6, still preferably 1-4, and most preferably 1-2; the halogens in the polyhaloalkyl are preferably one or more of fluorine, bromine and iodine; the number of the halogens in the polyhaloalkyl is preferably 2-4, and more preferably 3-4; the substituents in the substituted aryl and the substituted isocyanatourea ester group each are independently one or more selected from C₁-C₈ alkyl, C₆-C₁₀ aryl, hydroxyl, carbonyl and an ether group. In the present disclosure, the used light-absorbing organic chromophore may vary according to different exposure irradiations, and for example, for exposure irradiation with a wavelength of 248 nm, it is preferred that the light-absorbing organic chromophore is one or more selected from a group consisting of substituted or unsubstituted naphthyl and substituted or unsubstituted anthryl; for exposure irradiation with a wavelength of 193 nm, it is preferred that the light-absorbing organic chromophore is one or more of substituted or unsubstituted naphthyl and substituted or unsubstituted phenyl. In the present disclosure, the mass of the monomer unit containing light-absorbing chromophores is preferably 10%-85%, more preferably 15%-60%, and further preferably 20%-60%, of the mass of the organic polymer.

According to the present disclosure, the anti-reflective coating composition further comprises a thermal acid generator, a photoacid generator, a surfactant and a solvent.

Among them, the mass of the thermal acid generator is 0.01%-15%, preferably 0.01%-10%, more preferably 0.01%-5%, further preferably 0.01%-2%, still preferably 0.01%-1%, and most preferably 0.05%-0.5%, of the mass of the anti-reflective coating composition; the thermal acid generator is preferably selected from a group consisting of an ionic thermal acid generator and/or a non-ionic thermal acid generator; the ionic thermal acid generator is preferably one or more selected from a group consisting of a dodecylsulfonic acid triethylamine salt, a p-toluenesulfonic acid amine salt and a p-toluenesulfonate; the sulfononic acid salts are preferably one or more selected from a group consisting of carbocyclic aryl sulfonate, heteroaryl sulfonate, aliphatic sulfonate, benzenesulfonate and triflate; the non-ionic thermal acid generator is preferably one or more selected from a group consisting of trifluoro-methanesulfonic acid cyclohexyl ester, methyl trifluoromethanesulfonate, 2,4,6-triisopropylbenzenesulfonic acid cyclohexyl ester, 2-nitrobenzyl p-toluenesulfonate, benzoin tosylate, 2-nitrobenzyl tosylate, hexahydro-1,3,5-tris(2,3-dibromopropyl)-1,3,5-triazine-2,4,6-trione, organic sulfonic acid alkyl ester, p-toluenesulfonic acid, dodecylbenzenesulfonic acid, oxalic acid, phthalic acid, phosphoric acid, camphorsulfonic acid and salts of the above materials, or those disclosed in U.S. Pat. No. 10/429,737B2.

The mass of the photoacid generator is preferably 0%-15%, more preferably 0.01%-10%, even more preferably 0.01%-8%, further preferably 0.01%-5%, even further preferably 0.01%-2%, still preferably 0.01%-1%, and most preferably 0.01%-0.5%, of the mass of the anti-reflective coating composition; the photoacid generator is not particularly limited as long as it is a photoacid generator well known to those skilled in the art, and in the present disclosure, it is preferably one or more of onium salt photoacid generators, nitrobenzyl derivatives, sulfonate photoacid generators, diazomethane derivatives, glyoxime derivatives, sulfonate derivatives of N-hydroxyimide compounds, and halogen-containing triazine compounds, and more preferably one or more selected from a group consisting of iodonium (tetra-t-butylphenyl)-triflate, sulfonium triphenytriflate, triphenylsulfonium triflate, (p-tert-butoxyphenyl)diphenylsulfonium triflate, tris(p-t-butoxyphenyl) sulfonium trifluoromethanesulfonate, triphenylsulfonium p-toluenesulfonate, 2-nitrobenzyl-p-toluenesulfonate, 2,6-dinitrobenzyl-p-toluenesulfonate, 2,4-dinitrobenzyl-p-toluenesulfonate, benzoin tosylate, N-hydroxysuccinimide trifluoromethanesulfonic acid ester, 1,2,3-tris(methanesulfonyloxy)benzene, 1,2,3-tris(trifluoromethanesulfonyloxy)benzene, 1,2,3-tris(p-toluenesulfonyloxy)benzene, bis(benzenesulfonyl)azimethane, bis(p-toluenesulfonyl)azimethane, bis-O-(p-toluenesulfonyl)-a-dimethylglyoxime, bis-O-(n-butanesulfonyl)-a-dimethylglyoxime, N-hydroxysuccinimide methanesulfonate, N-hydroxysuccinimide triflate, phenylbis(trichloromethyl)-s-triazine, 2-(4-methoxyphenyl)-4,6-bis(trichloromethyl)-1,3,5-triazine and 2-(4-methoxynaphthyl)-4,6-bis(trichloromethyl)-1,3,5-triazine.

The mass of the surfactant is preferably 0%-20%, more preferably 0%-15% and further preferably 1%-10%, of the mass of the anti-reflective coating composition; the surfactant is preferably a nonionic surfactant, and more preferably one or more selected from a group consisting of polyoxyethylene lauryl (dodecyl) ether, polyoxyethylene stearyl ether, polyoxyethylene hexadecyl ether, polyoxyethylene oleyl ether, polyoxyethylene octylphenol ether, polyoxyethylene nonylphenol ether, polyoxyethylene-polyoxypropylene block copolymer, sorbitan monolaurate, sorbitan monopalmitate (hexadecanoate), sorbitan monostearate, sorbitan monooleate (9-octadecenate), sorbitan trioleate, sorbitan tristearate, polyoxyethylene sorbitan monolaurate, polyoxyethylene sorbitan monopalmitate (hexadecanoate), polyoxyethylene sorbitan monostearate, polyoxyethylene sorbitan monooleate (9-octadecenate), polyoxyethylene sorbitan trioleate, and polyoxyethylene sorbitan tristearate.

The mass of the solvent is preferably 90-99%, more preferably 95-99%, and further preferably 95-97%, of the mass of the anti-reflective coating composition; the solvent is not particularly limited as long as it is an organic solvent well known to those skilled in the art, and in the present disclosure, it is preferably one or more of alcohol, ester, ether and cyclic ketone solvents, and more preferably one or more selected from a group consisting of ethylene glycol monomethyl ether, ethylene glycol monoethyl ether, methylcellosolve acetate, ethylcellosolve acetate, diethylene glycol monomethyl ether, diethylene glycol diethyl ether, propylene glycol, propylene glycol monomethyl ether, propylene glycol monomethyl ether acetate, propylene glycol propyl ether acetate, toluene, xylene, methyl ethyl ketone, cyclopentanone, cyclohexanone, ethyl 2-hydroxypropionate, methyl 2-hydroxy-3-methylbutyrate, methyl 3-methoxypropionate, ethyl 3-methoxypropionate, ethyl 3-ethoxypropionate, methyl 3-ethoxypropionate, methyl pyruvate, ethyl pyruvate, ethyl acetate, butyl acetate, ethyl lactate, butyl lactate, N,N-dimethylformamide (DMF), and N-methylpyrrolidone.

The crosslinkable polymer provided by the present disclosure comprises a monomer unit that can be self-crosslinked with a functional group such as hydroxyl, amino, sulfhydryl and the like, so that it does not need to add a crosslinking agent to a coating layer. Gas generation of a composition during its baking can be effectively solved or avoided. By taking a hydroxyl group as an example of the functional group, its crosslinking mechanism is described below:

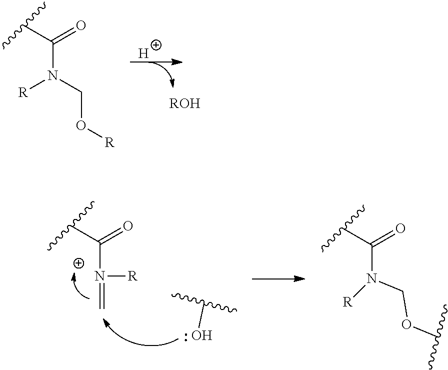

The present disclosure further provides the application of the above anti-reflective coating composition in a photolithographic process; the anti-reflective coating composition is disposed between the photoresist layer and the substrate to form an anti-reflective coating layer that can reduce reflections of exposure irradiations from the substrate to the photoresist; the thickness of the anti-reflective coating layer is preferably 10 nm-100 nm, and more preferably 33 nm-100 nm.

The present disclosure also provides a method for forming a pattern image with photoresist during manufacturing semiconductor device, comprising a film-forming step of the above anti-reflective coating composition, a film-forming step of the photoresist, and subsequent irradiation-exposing step followed by the developing step of photoresist.

To further illustrate the present disclosure, the following examples are combined to describe in detail the anti-reflective coating composition and crosslinkable polymer provided by the present disclosure.

All reagents used in the following examples are commercially available.

### Example 1

900 mg of N-(methoxymethyl) methacrylamide, 1.92 g of methyl methacrylate, 780 mg of 2-hydroxyethyl methacrylate and 1.42 g of benzyl methacrylate were dissolved in 15 mL of tetrahydrofuran, and 70 mg of azobisisobutyronitrile (AIBN) were added thereto. They were heated to reflux and reacted for 24 hours. A produced polymer was precipitated with n-hexane and dried by heating in a drying oven, to make a desired polymer.

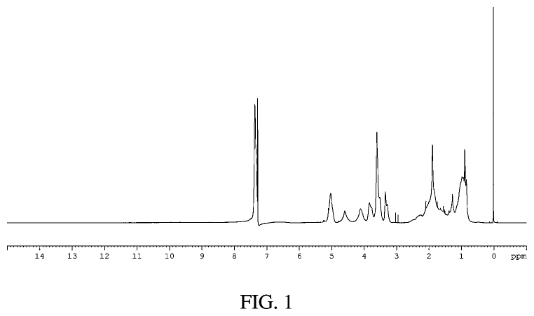

The polymer obtained in Example 1 was analyzed with nuclear magnetic resonance, to obtain its Hydrogen Nuclear Magnetic Resonance spectrogram, as shown in FIG. 1.

### Example 2

2.3 g of methyl methacrylate and 2.6 g of N-(methoxymethyl) methacrylamide were dissolved in 10 mL of tetrahydrofuran, and 500 mg of azobisisobutyronitrile (AIBN) were added thereto. They were heated to reflux and reacted for 24 hours. A produced polymer was precipitated with n-hexane and dried by heating in a drying oven, to make a desired polymer.

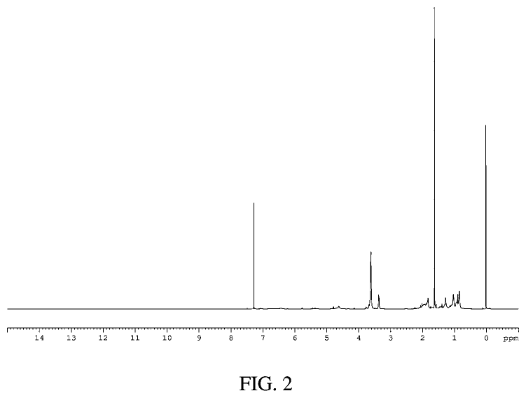

The polymer obtained in Example 2 was analyzed with nuclear magnetic resonance, to obtain its Hydrogen Nuclear Magnetic Resonance spectrogram, as shown in FIG. 2.

### Example 3

1.2 g of methyl methacrylate and 3.8 g of N-(methoxymethyl) methacrylamide were dissolved in 10 mL of tetrahydrofuran, and 250 mg of azobisisobutyronitrile (AIBN) were added thereto. They were heated to reflux and reacted for 24 hours. A produced polymer was precipitated with n-hexane and dried by heating in a drying oven, to make a desired polymer.

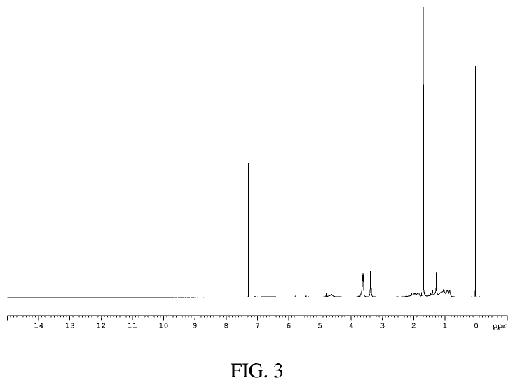

The polymer obtained in Example 3 was analyzed with nuclear magnetic resonance, to obtain its Hydrogen Nuclear Magnetic Resonance spectrogram, as shown in FIG. 3.

### Example 4

2.8 g of glycidyl methacrylate were dissolved in 8 mL of tetrahydrofuran, and 300 mg of azobisisobutyronitrile (AIBN) were added thereto. They were heated to reflux and reacted for 24 hours. A produced polymer was precipitated with n-hexane and dried by heating in a drying oven. The obtained resin and 4.4 g of 9-anthracenecarboxylic acid were dissolved in 12 mL of propylene glycol monomethyl ether, and 700 mg of benzyltriethylammonium chloride were added thereto. They were reacted at 110° C. for 24 hours, and the produced polymer was precipitated with n-hexane and dried by heating in a drying oven, to make a desired polymer.

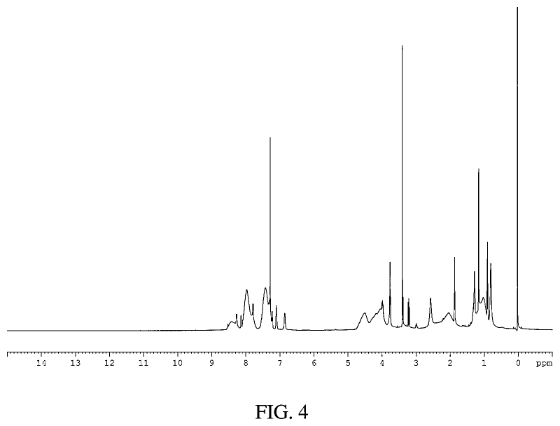

The polymer obtained in Example 4 was analyzed with nuclear magnetic resonance, to obtain its Hydrogen Nuclear Magnetic Resonance spectrogram, as shown in FIG. 4.

### Example 5

520 mg of 2-hydroxyethyl methacrylate, 600 mg of methyl methacrylate, and 1.62 g of benzyl methacrylate were dissolved in 10 mL of tetrahydrofuran, and 160 mg of azobisisobutyronitrile (AIBN) were added thereto. They were heated to reflux and reacted for 24 hours. A produced polymer was precipitated with n-hexane and dried by heating in a drying oven, to make a desired polymer.

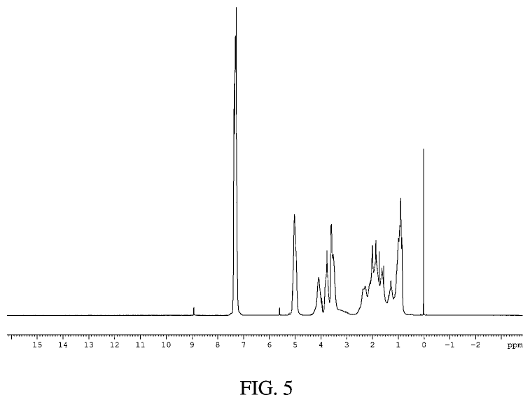

The polymer obtained in Example 5 was analyzed with nuclear magnetic resonance, to obtain its Hydrogen Nuclear Magnetic Resonance spectrogram, as shown in FIG. 5.

### Example 6

5.2 g of 1,3, 5-tris(2-hydroxyethyl)cyanuric acid, 7.76 g of dimethyl terephthalate, 1.84 g of glycerol and 90 mg of p-toluenesulfonic acid were heated to 150° C. and reacted for 24 hours. A produced polymer was precipitated with t-butyl methyl ether and dried by heating in a drying oven, to make a desired polymer.

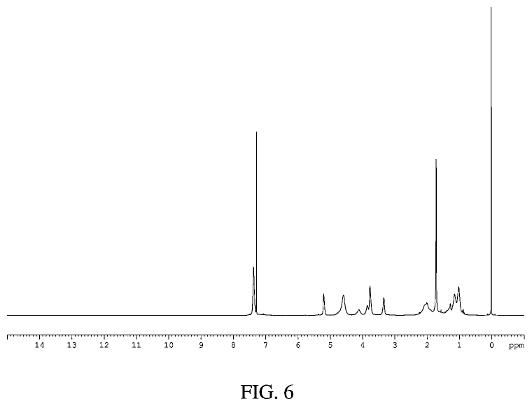

The polymer obtained in Example 6 was analyzed with nuclear magnetic resonance, to obtain its Hydrogen Nuclear Magnetic Resonance spectrogram, as shown in FIG. 6.

### Example 7

1.1 g of 9-anthracenemethyl methacrylate, 520 mg of 2-hydroxyethyl methacrylate and 656 mg of N-(methoxymethyl) methacrylamide were dissolved in 6 ml of tetrahydrofuran, and 90 mg of azobisisobutyronitrile (AIBN) were added thereto. They were heated to reflux and reacted for 24 hours. A produced polymer was precipitated with n-hexane and dried by heating in a drying oven, to make a desired polymer.

The polymer obtained in Example 7 was analyzed with nuclear magnetic resonance, to obtain its Hydrogen Nuclear Magnetic Resonance spectrogram, as shown in FIG. 7.

### Example 8

To 10 g of ethyl lactate containing 0.4 g of the polymer obtained in Example 1, 10 mg of toluenesulfonic acid was added. A formulated solution was filtered through a 0.2 μm polyethylene microporous filter, to make an anti-reflective coating composition.

The composition was spin coated on a silicon wafer with a spinning coater and heated with a 205° C. electric hotplate for one minute, to form an 85 nm anti-reflective film. The film was measured by a spectroscopic ellipsometer to obtain a refractive index n at 193 nm of 1.79 and an extinction coefficient k of 0.34.

### Example 9

To 10 g of ethyl lactate containing 0.2 g of the polymer obtained in Example 3 and 0.1 g of the polymer obtained in Example 4, 10 mg of p-toluenesulfonic acid was added. The formulated solution was filtered through a 0.2 μm polyethylene microporous filter, to make an anti-reflective coating composition.

The composition was spin coated on a silicon wafer with a spinning coater and heated with a 205° C. electric hotplate for one minute, to form a 33 nm anti-reflective film. The film was measured by a spectroscopic ellipsometer to obtain a refractive index n at 248 nm of 1.44 and an extinction coefficient k of 0.38.

### Example 10

To 10 g of methyl 2-hydroxyisobutyrate containing 0.4 g of the polymer obtained in Example 6 and 0.075 g of the polymer obtained in Example 2, 10 mg of toluenesulfonic acid was added. The formulated solution was filtered through a 0.2 μm polyethylene microporous filter, to make an anti-reflective coating composition.

The composition was spin coated on a silicon wafer with a spinning coater and heated with a 205° C. electric hotplate for one minute, to form a 61 nm anti-reflective film. The film was measured by a spectroscopic ellipsometer to obtain a refractive index n at 193 nm of 1.75 and an extinction coefficient k of 0.43.

### Example 11

To 10 g of ethyl lactate containing 200 mg of the polymer obtained in Example 5 and 200 mg of the polymer obtained in Example 2, 10 mg of toluenesulfonic acid was added. The formulated solution was filtered through a 0.2 μm polyethylene microporous filter, to make an anti-reflective coating composition.

The composition was spin coated on a silicon wafer with a spinning coater and heated with a 205° C. electric hotplate for one minute, to form a 44 nm anti-reflective film. The film was measured by a spectroscopic ellipsometer to obtain a refractive index n at 193 nm of 1.81 and an extinction coefficient k of 0.33.

### Example 12

To 10 g of ethyl lactate containing 0.4 g of the polymer obtained in Example 7, 10 mg of toluenesulfonic acid was added. The formulated solution was filtered through a 0.2 μm polyethylene microporous filter, to make an anti-reflective coating composition.

The composition was spin coated on a silicon wafer with a spinning coater and heated with a 205° C. electric hotplate for one minute, to form a 58 nm anti-reflective film. The film was measured by a spectroscopic ellipsometer to obtain t a refractive index n at 248 nm of 1.46 and an extinction coefficient k of 0.48.

### Comparative Example 1

To 10 g of ethyl lactate containing 0.4 g of the polymer obtained in Example 7, 100 mg of TMGU (tetramethoxymethylglycoluril) and 10 mg of p-toluenesulfonic acid were added. The formulated solution was filtered through a 0.2 μm polyethylene microporous filter, to make an anti-reflective coating composition.

The composition was spin coated on a silicon wafer with a spinning coater and heated with a 205° C. electric hotplate for one minute, to form a 58 nm anti-reflective film. The film was measured by a spectroscopic ellipsometer to obtain a refractive index n at 193 nm of 1.77 and an extinction coefficient k of 0.44.

The compositions obtained in Examples 8 to 12 were coated on silicon wafers by a spin coater, and heated with a 205° C. electric hotplate for 60 seconds, to obtain corresponding anti-reflective films that were measured with their film thicknesses. The films were immersed in a photoresist solvent such as ethyl lactate, propylene glycol monomethyl ether, and the like, for 20 seconds. The films were baked at 100ºC for 30 seconds and then their film thicknesses were measured again. As for the compositions of Examples 8 to 12, the differences between the two former and latter film measurements each were less than 1 nm, to confirm that the anti-reflective films were insoluble in the solvents used for the photoresist.

The compositions obtained in the Examples 8 to 12 were coated on silicon wafers by a spin coater, and heated with a 205° C. electric hotplate for 60 seconds, to obtain corresponding anti-reflective films with the same thicknesses a. The films were immersed in propylene glycol monomethyl ether for 40 seconds, and baked at 100° ° C. for 30 seconds and then their film thicknesses were measured again, the measured film thickness is b. Then the films were immersed in ethyl lactate for 40 seconds, and baked at 100° ° C. for 30 seconds and then their film thicknesses were measured again, the measured film thickness is c.

Calculate the film thickness b/film thickness a, film thickness c/film thickness a, and record them in Table 1.

TABLE 1

| | film thickness b/film | |
|---|---|---|
| | thickness a | film thickness c/film |
| | (%) | thickness a (%) |
| Example8 | 98.3 | 98.0 |
| Example9 | 92.1 | 88.9 |
| Example10 | 99.2 | 98.1 |
| Example11 | 98.2 | 97.9 |
| Example12 | 90.3 | 87.2 |

From Table 1, it can be seen that the anti-reflective film prepared by the composition of Examples 8, 10, and 11 has a higher retention rate of film thickness after being immersed in propylene glycol monomethyl ether and ethyl lactate, indicating that the corresponding anti-reflective film has better solvent resistance. It can be seen that polymers without aromatic groups or with monocyclic aromatic groups in monomer unit have better film thickness integrity when used in conjunction with photoresist.

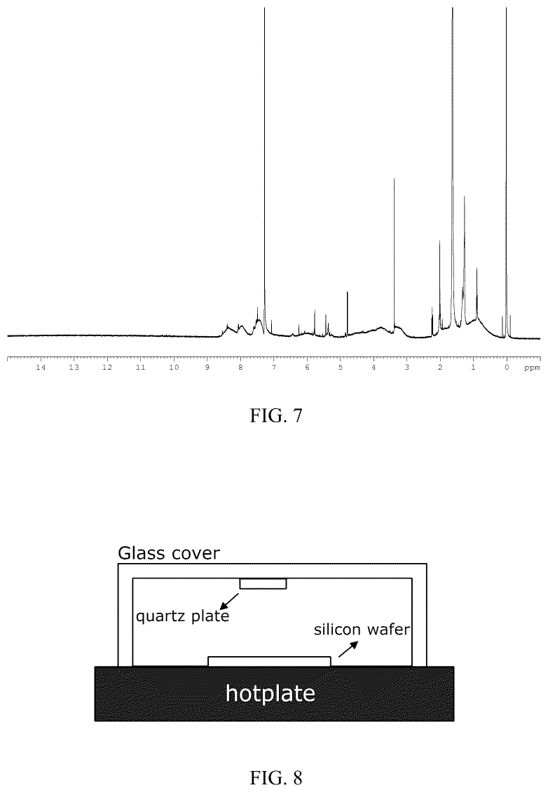

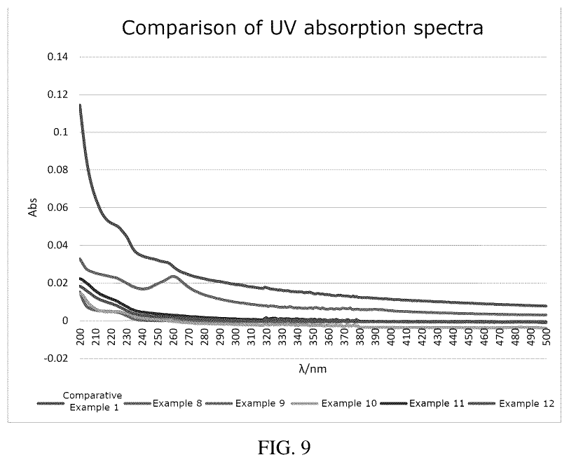

The outgassing effect was evaluated according to the following method. The anti-reflective coating compositions obtained in Examples 8 to 12 and Comparative Example 1 were spin coated on a silicon wafer by a spin coater with a thickness of 60±3 nm, respectively, and upon heating and baking with a 205° C. electric hotplate, a quartz plate was placed at 3 cm above the silicon wafer for receiving outgassing (the specific apparatus is shown in FIG. 8). After repeating the spin coating for five times, the obtained quartz plates were measured by an ultraviolet Spectrophotometer (UV/Vis/NIR Spectrophotometer LAMBDA 1050+), and the obtained results were shown in FIG. 9.

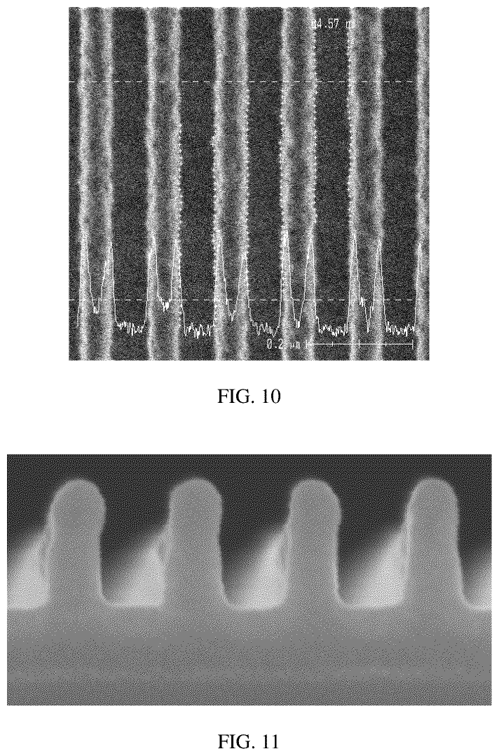

The lithographic effect was evaluated according to the following method. The anti-reflective coating composition of Example 8 was coated on a 200 mm silicon wafer and baked on a 205° C. hotplate for 60 seconds. The spinning time and speed were varied according to the need to obtain an 87 nm thick film. Next, on the anti-reflective coating layer, a positive photoresist was spin coated and cured by baking to obtain a 166 nm thick photoresist layer. An ArF scanner with a numerical aperture of 1.1 was utilized for irradiation exposure, and the irradiation-exposed photoresist was baked at 115° C. for 60 seconds. Thereafter, a tetramethylammonium hydroxide developer was utilized for development. The obtained patterns were checked with a Scanning Electron Microscope (SEM) to obtain FIG. 10 and FIG. 11.

What is claimed is:

1. An anti-reflective coating composition, wherein comprising an organic polymer;
the organic polymer comprises a crosslinkable polymer;
the crosslinkable polymer comprises a monomer unit formed by a monomer represented by formula (I): 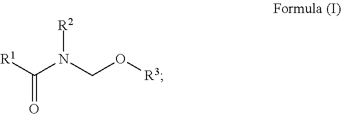
wherein R¹ is selected from substituted or unsubstituted C₂-C₁₀ alkenyl;
R² and R³ each are independently selected from a group consisting of H, substituted or unsubstituted C₁-C₆ alkyl, and substituted or unsubstituted C₆-C₂₀ aryl;
substituents in the substituted C₂-C₁₀ alkenyl, substituted C₁-C₆ alkyl, and substituted C₆-C₂₀ aryl each are independently one or more selected from a group consisting of C₁-C₈ alkyl, C₁-C₆ alkoxy and phenyl.

2. The anti-reflective coating composition according to claim 1, wherein R¹ is selected from substituted or unsubstituted C₂-C₄ alkenyl;
R² and R³ each are independently selected from a group consisting of H, substituted or unsubstituted C₁-C₃ alkyl, and substituted or unsubstituted C₆-C₁₀ aryl.

3. The anti-reflective coating composition according to claim 1, wherein the mass of the organic polymer is 2%-10% of the mass of the anti-reflective coating composition; the mass of the crosslinkable polymer is 10%-100% of the mass of the organic polymer; the amount of the monomer unit formed by the monomer represented by formula (I) in the crosslinkable polymer is 5 wt %-80 wt %.

4. The anti-reflective coating composition according to claim 1, wherein the crosslinkable polymer comprises a functional group and/or the organic polymer further comprises a first polymer; the first polymer comprises a functional group; the functional group is one or more selected from a group consisting of hydroxyl, amino and sulfhydryl.

5. The anti-reflective coating composition according to claim 4, wherein the mass of the monomer unit comprising the functional group is 20%-300% of the mass of the monomer unit formed by the monomer represented by formula (I).

6. The anti-reflective coating composition according to claim 4, wherein the crosslinkable polymer further comprises a light-absorbing organic chromophore and/or the first polymer further comprises a light-absorbing organic chromophore and/or the organic polymer further comprises a second polymer; the second polymer comprises a light-absorbing organic chromophore; the light-absorbing organic chromophore is one or more selected from a group consisting of substituted or unsubstituted aryl, polyhaloalkyl, and a substituted or unsubstituted isocyanatourea group, preferably the substituted or unsubstituted aryl is one or more selected from a group consisting of substituted or unsubstituted monocyclic aryl or substituted or unsubstituted polycyclic aryl, more preferably substituted or unsubstituted phenyl, substituted or unsubstituted naphthyl, substituted or unsubstituted anthryl, or substituted or unsubstituted quinolyl.

7. The anti-reflective coating composition according to claim 6, wherein the mass of the monomer unit comprising the light-absorbing organic chromophore is 10%-85% of the mass of the organic polymer.

8. The anti-reflective coating composition according to claim 1, wherein the anti-reflective coating composition further comprises a thermal acid generator, a photoacid generator, a surfactant and a solvent; the mass of the thermal acid generator is 0.1%-15% of the mass of the anti-reflective coating composition; the mass of the photoacid generator is 0%-15% of the mass of the anti-reflective coating composition; the mass of the surfactant is 0%-20% of the mass of the anti-reflective coating composition; the mass of the solvent is 90%-99% of the mass of the anti-reflective coating composition.

9. The anti-reflective coating composition according to claim 8, wherein the thermal acid generator is selected from a group consisting of ionic thermal acid generators and/or non-ionic thermal acid generators; the ionic thermal acid generators are one or more selected from a group consisting of a dodecylsulfonic acid triethylamine salt, a p-toluenesulfonic acid amine salt and a p-toluenesulfonate; the non-ionic thermal acid generators are one or more selected from a group consisting of a trifluoro-methanesulfonic acid cyclohexyl ester, methyl trifluoromethanesulfonate, 2,4,6-triisopropylbenzenesulfonic acid cyclohexyl ester, 2-nitrobenzyl p-toluenesulfonate, benzoin tosylate, 2-nitrobenzyl tosylate, hexahydro-1,3,5-tris(2,3-dibromopropyl)-1,3,5-triazine-2,4,6-trione, organic sulfonic acid alkyl ester, p-toluenesulfonic acid, dodecylbenzenesulfonic acid, oxalic acid, phthalic acid, phosphoric acid, camphorsulfonic acid and salts of the above materials;
the photoacid generator is one or more selected from a group consisting of iodonium (tetra-t-butylphenyl)-triflate, sulfonium triphenytriflate, triphenylsulfonium trifluoromethanesulfonate, (p-t-butoxyphenyl)diphenylsulfonium triflate, tris(p-t-butoxyphenyl)sulfonium triflate, triphenylsulfonium p-toluenesulfonate, 2-nitrobenzyl-p-toluenesulfonate, 2,6-dinitrobenzyl-p-toluenesulfonate, 2,4-dinitrobenzyl-p-toluenesulfonate, benzoin tosylate, N-hydroxysuccinimide trifluoromethanesulfonic acid ester, 1,2,3-tris(methanesulfonyloxy)benzene, 1,2,3-tris(trifluoromethanesulfonyloxy)benzene, 1,2,3-tris(p-toluenesulfonyloxy)benzene, bis(benzenesulfonyl)azimethane, bis(p-toluenesulfonyl)azimethane, bis-O-(p-toluenesulfonyl)-a-dimethylglyoxime, bis-O-(n-butanesulfonyl)-a-dimethylglyoxime, N-hydroxysuccinimide methanesulfonate, N-hydroxysuccinimide triflate, phenylbis(trichloromethyl)-s-triazine, 2-(4-methoxyphenyl)-4,6-bis(trichloromethyl)-1,3,5-triazine and 2-(4-methoxynaphthyl)-4,6-bis(trichloromethyl)-1,3,5-triazine;
the surfactant is one or more selected from a group consisting of polyoxyethylene lauryl (dodecyl) ether, polyoxyethylene stearyl ether, polyoxyethylene hexadecyl ether, polyoxyethylene oleyl ether, polyoxyethylene octylphenol ether, polyoxyethylene nonylphenol ether, polyoxyethylene-polyoxypropylene block copolymer, sorbitan monolaurate, sorbitan monopalmitate (hexadecanoate), sorbitan monostearate, sorbitan monooleate (9-octadecenate), sorbitan trioleate, sorbitan tristearate, polyoxyethylene sorbitan monolaurate, polyoxyethylene sorbitan monopalmitate (hexadecanoate), polyoxyethylene sorbitan monostearate, polyoxyethylene sorbitan monooleate (9-octadecenate), polyoxyethylene sorbitan trioleate, and polyoxyethylene sorbitan tristearate;
the solvent is one or more selected from a group consisting of ethylene glycol monomethyl ether, ethylene glycol monoethyl ether, methylcellosolve acetate, ethylcellosolve acetate, diethylene glycol monomethyl ether, diethylene glycol monoethyl ether, propylene glycol, propylene glycol monomethyl ether, propylene glycol monomethyl ether acetate, propylene glycol propyl ether acetate, toluene, xylene, methyl ethyl ketone, cyclopentanone, cyclohexanone, ethyl 2-hydroxypropionate, methyl 2-hydroxy-3-methylbutyrate, methyl 3-methoxypropionate, ethyl 3-methoxypropionate, ethyl 3-ethoxypropionate, methyl 3-ethoxypropionate, methyl pyruvate, ethyl pyruvate, ethyl acetate, butyl acetate, ethyl lactate, butyl lactate, N,N-dimethylformamide, and N-methylpyrrolidone.

10. A crosslinkable polymer, wherein it comprises a monomer unit formed by a monomer represented by formula (I); 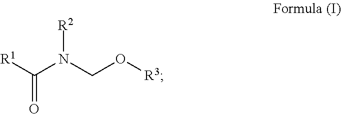
wherein R¹ is selected from substituted or unsubstituted C₂-C₁₀ alkenyl, preferably substituted or unsubstituted C₂-C₈ alkenyl, more preferably substituted or unsubstituted C₂-C₆ alkenyl, further preferably substituted or unsubstituted C₂-C₄ alkenyl, and most preferably C₂-C₃ alkenyl; the number of the double bonds in the alkenyl may be one or more; the number of the double bonds in the alkenyl is preferably 1 to 2, and more preferably 1;
R² and R³ each are independently selected from a group consisting of H, substituted or unsubstituted C₁-C₆ alkyl, and substituted or unsubstituted C₆-C₂₀ aryl, preferably selected from a group consisting of H, substituted or unsubstituted C₁-C₆ alkyl, and substituted or unsubstituted C₆-C₁₅ aryl, more preferably selected from a group consisting of H, substituted or unsubstituted C₁-C₄ alkyl, and substituted or unsubstituted C₆-C₁₀ aryl, and further preferably selected from a group consisting of H, substituted or unsubstituted C₁-C₂ alkyl, and substituted or unsubstituted phenyl;
substituents in the substituted C₂-C₁₀ alkenyl, substituted C₁-C₆ alkyl, and substituted C₆-C₂₀ aryl each are independently one or more selected from a group consisting of C₁-C₈ alkyl, C₁-C₆ alkoxy and phenyl, preferably selected from a group consisting of C₁-C₃ alkyl or phenyl, and more preferably selected from a group consisting of methyl, ethyl, C₁-C₆ alkoxy or phenyl.

11. A method for preparation of the crosslinkable polymer according to claim 10, including by mixing monomers, represented by formula (I), with an initiator in a solvent and heating them to conduct a polymerization reaction.

12. A method for forming a pattern image with photoresist during manufacturing semiconductor device, wherein it comprises a film-forming step of the anti-reflective coating composition according to claim 1, a film-forming step of photoresist, and subsequent irradiation-exposing step followed by the developing step of photoresist.

13. The anti-reflective coating composition according to claim 1, wherein an amount of the monomer unit formed by the monomer represented by formula (I) in the crosslinkable polymer is 5 wt %-80 wt %, preferably 10 wt %-76 wt %, more preferably 15 wt %-55 wt %, and further preferably 15 wt %-53 wt %.

14. The anti-reflective coating composition according to claim 1, wherein the crosslinkable polymer comprises an acrylates monomer unit, the acrylates monomer for forming the acrylates monomer unit are preferably selected from a group consisting of substituted or unsubstituted alkyl acrylate and substituted or unsubstituted alkyl methacrylate; the number of carbon atoms in the alkyl groups of the substituted or unsubstituted alkyl acrylate and substituted or unsubstituted alkyl methacrylate is preferably 1-8, more preferably 1-6, and further preferably 1-4; the substituents in the substituted or unsubstituted alkyl acrylate and substituted or unsubstituted alkyl methacrylate each, independently, are preferably one or more selected from a group consisting of hydroxyl, amino, sulfhydryl, halogen and light-absorbing chromophore; the light-absorbing organic chromophore is preferably one or more selected from a group consisting of substituted or unsubstituted aryl, polyhaloalkyl, and a substituted or unsubstituted isocyanatourea ester group; wherein the substituted or unsubstituted aryl is substituted or unsubstituted monocyclic aryl or substituted or unsubstituted polycyclic aryl, preferably substituted or unsubstituted phenyl, substituted or unsubstituted naphthyl, substituted or unsubstituted anthryl, or substituted or unsubstituted quinolyl; the number of carbon atoms of the alkyl in the polyhaloalky is preferably 1-10, more preferably 1-8, further preferably 1-6, still preferably 1-4, and most preferably 1-2; the halogens in the polyhaloalkyl are preferably one or more of bromine and iodine; the number of the halogens in the polyhaloalkyl is preferably 2-4, and more preferably 3-4; the substituents in the substituted aryl and substituted isocyanatourea ester group each are independently one or more selected from a group consisting of C1-C8 alkyl, C6-C10 aryl, hydroxyl, carbonyl and ether group.

15. The anti-reflective coating composition according to claim 1, wherein the acrylates monomer unit in the crosslinkable polymer comprises a substituted acrylates monomer unit containing at least one of halogen and light-absorbing chromophore, and an acrylates monomer unit containing a functional group; the functional group is preferably one or more selected from a group consisting of hydroxyl, amino and sulfhydryl; the mass of the acrylates monomer unit containing the functional group is preferably 5%-50%, more preferably 5%-30%, further preferably 10%-30%, still preferably 15%-25%, and most preferably 15%-20%, of the mass of the acrylate monomer unit in the crosslinkable polymer; the mass of the substituted acrylates monomer unit containing at least one of the halogen and the light-absorbing chromophore is preferably 10%-50%, more preferably 20%-50%, further preferably 30%-50%, still preferably 30%-40%, and most preferably 34%-40%, of the mass of the acrylate monomer unit in the crosslinkable polymer.

16. The crosslinkable polymer according to claim 10, wherein an amount of the monomer unit formed by the monomer represented by formula (I) in the crosslinkable polymer is 5 wt %-80 wt %, preferably 10 wt %-76 wt %, more preferably 15 wt %-55 wt %, and further preferably 15 wt %-53 wt %.

17. The crosslinkable polymer according to claim 10, wherein the crosslinkable polymer comprises an acrylates monomer unit, the acrylates monomer for forming the acrylates monomer unit are preferably selected from a group consisting of substituted or unsubstituted alkyl acrylate and substituted or unsubstituted alkyl methacrylate; the number of carbon atoms in the alkyl groups of the substituted or unsubstituted alkyl acrylate and substituted or unsubstituted alkyl methacrylate is preferably 1-8, more preferably 1-6, and further preferably 1-4; the substituents in the substituted or unsubstituted alkyl acrylate and substituted or unsubstituted alkyl methacrylate each, independently, are preferably one or more selected from a group consisting of hydroxyl, amino, sulfhydryl, halogen and light-absorbing chromophore; the light-absorbing organic chromophore is preferably one or more selected from a group consisting of substituted or unsubstituted aryl, polyhaloalkyl, and a substituted or unsubstituted isocyanatourea ester group; wherein the substituted or unsubstituted aryl is substituted or unsubstituted monocyclic aryl or substituted or unsubstituted polycyclic aryl, preferably substituted or unsubstituted phenyl, substituted or unsubstituted naphthyl, substituted or unsubstituted anthryl, or substituted or unsubstituted quinolyl; the number of carbon atoms of the alkyl in the polyhaloalky is preferably 1-10, more preferably 1-8, further preferably 1-6, still preferably 1-4, and most preferably 1-2; the halogens in the polyhaloalkyl are preferably one or more of bromine and iodine; the number of the halogens in the polyhaloalkyl is preferably 2-4, and more preferably 3-4; the substituents in the substituted aryl and substituted isocyanatourea ester group each are independently one or more selected from a group consisting of C1-C8 alkyl, C6-C10 aryl, hydroxyl, carbonyl and ether group.

18. The crosslinkable polymer according to claim 10, wherein the acrylates monomer unit in the crosslinkable polymer comprises a substituted acrylates monomer unit containing at least one of halogen and light-absorbing chromophore, and an acrylates monomer unit containing a functional group; the functional group is preferably one or more selected from a group consisting of hydroxyl, amino and sulfhydryl; the mass of the acrylates monomer unit containing the functional group is preferably 5%-50%, more preferably 5%-30%, further preferably 10%-30%, still preferably 15%-25%, and most preferably 15%-20%, of the mass of the acrylate monomer unit in the crosslinkable polymer; the mass of the substituted acrylates monomer unit containing at least one of the halogen and the light-absorbing chromophore is preferably 10%-50%, more preferably 20%-50%, further preferably 30%-50%, still preferably 30%-40%, and most preferably 34%-40%, of the mass of the acrylate monomer unit in the crosslinkable polymer.
